(19) United States
(12) Patent Application Publication
(10) Pub. No.: US 2015/0179099 A1
(43) Pub. Date: Jun. 25, 2015

(54) MOTHER SUBSTRATE FOR ORGANIC LIGHT-EMITTING DISPLAY DEVICE AND ORGANIC LIGHT-EMITTING DISPLAY DEVICE

(71) Applicant: Samsung Display Co., Ltd., Yongin-City (KR)

(72) Inventor: Jae-Kyung Go, Yongin-City (KR)

(73) Assignee: Samsung Display Co., Ltd., Yongin-City (KR)

(21) Appl. No.: 14/273,337

(22) Filed: May 8, 2014

(30) Foreign Application Priority Data
Dec. 23, 2013 (KR) 10-2013-0161782

(51) Int. Cl. G09G 3/32

(52) U.S. Cl. CPC G09G 3/3208; G09G 2360/141

(57) ABSTRACT

A mother substrate for organic light-emitting display device includes a base substrate, a plurality of display areas arranged in an array on the base substrate, the array having a plurality of rows and a plurality of columns that are perpendicular to the plurality of rows. The mother substrate further includes a plurality of first dummy patterns formed between the plurality of rows of display areas, and a plurality of second dummy patterns formed between the plurality of columns of display areas. Each of the plurality of first dummy patterns includes a top portion and a bottom portion, the bottom portion being closer to the base substrate than the top portion and having a width, in a column direction parallel to the plurality of columns, that is greater than a width of the top portion in the column direction.

### CROSS-REFERENCE TO RELATED APPLICATIONS

This application claims the benefit of Korean Patent Application No. 10-2013-0161782, filed on Dec. 23, 2013, in the Korean Intellectual Property Office, the disclosure of which is incorporated herein in its entirety by reference.

### BACKGROUND

1. Field

The described technology generally relates to a mother substrate for organic light-emitting display device, and an organic light-emitting display device.

2. Description of the Related Art

Organic light-emitting display devices are self-emissive and include a hole injection electrode and an electron injection electrode, and an organic emission layer (organic EML) formed therebetween. A hole injected from the hole injection electrode and an electrode injected from the electron injection electrode are combined in the organic EML to generate an exiton and light is emitted when the exiton falls from an excited state to a ground state.

Organic light-emitting display devices do not require a separate light source, are capable of operating with a low voltage, can be lightweight and slim, and are expected to become a next generation display device due to its high quality characteristics such as its wide viewing angle, high contrast, and fast response time.

### SUMMARY

One inventive aspect is a mother substrate for an organic light-emitting display device, and an organic light-emitting display device.

Additional aspects will be set forth in part in the description which follows and, in part, will be apparent from the description, or may be learned by practice of the presented embodiments.

According to one aspect, a mother substrate for organic light-emitting display device includes a base substrate, a plurality of display areas arranged in an array on the base substrate, the array having a plurality of rows and a plurality of columns that are perpendicular to the plurality of rows. The mother substrate further includes a plurality of first dummy patterns formed between the plurality of rows of display areas, and a plurality of second dummy patterns formed between the plurality of columns of display areas. Each of the plurality of first dummy patterns includes a top portion and a bottom portion, the bottom portion being closer to the base substrate than the top portion and having a width, in a column direction parallel to the plurality of columns, that is greater than a width of the top portion in the column direction.

According to another aspect, a mother substrate for organic light-emitting display device includes a base substrate whereon a plurality of display areas are defined; and a plurality of first dummy patterns and a plurality of second dummy patterns which are formed between the plurality of display areas, wherein the plurality of display areas are arrayed in parallel with each other and thus form a plurality of rows and a plurality of columns, and wherein the plurality of first dummy patterns are formed between and outside the plurality of rows, and each of the plurality of first dummy patterns includes a step.

Each of the plurality of first dummy patterns may include a first layer and a second layer on the first layer, and a width of the second layer may be smaller than a width of the first layer.

Each of the plurality of first dummy patterns may have a stair-shape in which an upper width is smaller than a lower width.

Each of the plurality of first dummy patterns may include a side surface that is a slope.

Each of the plurality of first dummy patterns may include a plurality of cut portions.

The plurality of cut portions may be separated from each other by a regular distance.

Each of the plurality of display areas may include a pixel unit including a thin-film transistor (TFT) and an organic light-emitting device, and a circuit unit including a power line, a planarization layer may be disposed between the TFT and the organic light-emitting device, and a portion of the planarization layer may form a passivation layer that covers an external portion of the power line.

The mother substrate for organic light-emitting display device may further include a step compensation layer formed at an external side of the passivation layer, and the step compensation layer may have a height that is smaller than a height of the passivation layer.

The step compensation layer may be continuously formed from the passivation layer.

The step compensation layer may be formed of the same material as the planarization layer.

The step compensation layer may have a slope whose height decreases as the slope slants toward an outside of the plurality of display areas.

The step compensation layer may be positioned outside the plurality of display areas.

The plurality of first dummy patterns and the plurality of second dummy patterns may be formed of a same material as the planarization layer.

The mother substrate for organic light-emitting display device may further include first cutting lines between the plurality of first dummy patterns and the plurality of display areas, and second cutting lines between the plurality of second dummy patterns and the plurality of display areas.

According to another aspect, an organic light-emitting display device includes a substrate for defining a display area, a pixel formed within the display area, a circuit formed within the display area and comprising a power line, and a step compensation layer formed outside the display area. The pixel comprises a thin-film transistor (TFT), an organic light-emitting diode (OLED), and a planarization layer between the TFT and the OLED. The planarization layer forms a passivation layer that covers an external portion of the power line. The step compensation layer is formed at an external side of the passivation layer that is farther away from the center of the display area, and has a height that is smaller than a height of the passivation layer.

According to another aspect, an organic light-emitting display device includes a substrate for defining a display area; a pixel unit formed within the display area; a circuit unit formed within the display area and including a power line; and a step compensation layer formed outside the display area, wherein the pixel unit includes a thin-film transistor (TFT), an organic light-emitting device, and a planarization layer between the TFT and the organic light-emitting device, wherein the planarization layer forms a passivation layer that covers an external portion of the power line, and wherein the step compensation layer is formed at an external side of the passivation layer, and has a height that is smaller than a height of the passivation layer.

The step compensation layer may be formed of a same material as the planarization layer.

The step compensation layer may be continuously formed from the passivation layer.

The step compensation layer may include a slope.

A height of the slope may decrease as the slope slants toward an outside of the display area.

### BRIEF DESCRIPTION OF THE DRAWINGS

These and/or other aspects will become apparent and more readily appreciated from the following description of the embodiments, taken in conjunction with the accompanying drawings in which:

FIG. 1 is a plan view illustrating an organic light-emitting display device according to an embodiment of the present disclosure;

FIG. 2 is a cross-sectional view of the organic light-emitting display device, taken along a line I-I of FIG. 1;

FIG. 3 is a plan view of a mother substrate for organic light-emitting display device, according to an embodiment of the present disclosure;

FIG. 4 is a cross-sectional view of the mother substrate for organic light-emitting display device, taken along a line II-II of FIG. 3;

FIG. 5 is another cross-sectional view of the mother substrate for organic light-emitting display device, taken along the line II-II of FIG. 3; and

FIG. 6 is a plan view illustrating a modified example of the mother substrate for organic light-emitting display device of FIG. 3.

### DETAILED DESCRIPTION

Numerous embodiments will be illustrated in the drawings and described in detail in the written description. However, this is not intended to limit the present invention to particular embodiments described herein or particular modes of practice thereof, and it is to be appreciated that all changes, equivalents, and substitutes that do not depart from the spirit and technical scope of the described technology present invention are encompassed in the present invention. In the present disclosure, certain detailed explanations of the related art are omitted when it is deemed that they may unnecessarily obscure the essence of the invention.

While such terms as “first,” “second,” etc., may be used to describe various components, such components must not be limited to the above terms. The above terms are used only to distinguish one component from another.

The terms used in the present disclosure are merely used to describe particular embodiments, and are not intended to limit the present invention. An expression used in the singular encompasses the expression of the plural, unless it has a clearly different meaning in the context. The drawings described are only schematic and are non-limiting. In the drawings, the size of some of the elements may be exaggerated and not drawn to scale for illustrative purposes.

It will be understood that when each element is referred to as being “on” or “under” another element, each element can be directly on or under another element, or an intervening element may also be present. The references with respect to being “on” or “under” are based on the drawings.

Embodiments will be described with reference to the accompanying drawings, wherein components that are the same as or similar to those of preceding embodiments are designated with the same reference numeral regardless of the figure number, and redundant explanations thereof are omitted. In this regard, the present embodiments may have different forms and should not be construed as being limited to the descriptions set forth herein. Accordingly, the embodiments are merely described below, by referring to the figures, to explain aspects of the described technology. As used herein, the term “and/or” includes any and all combinations of one or more of the associated listed items.

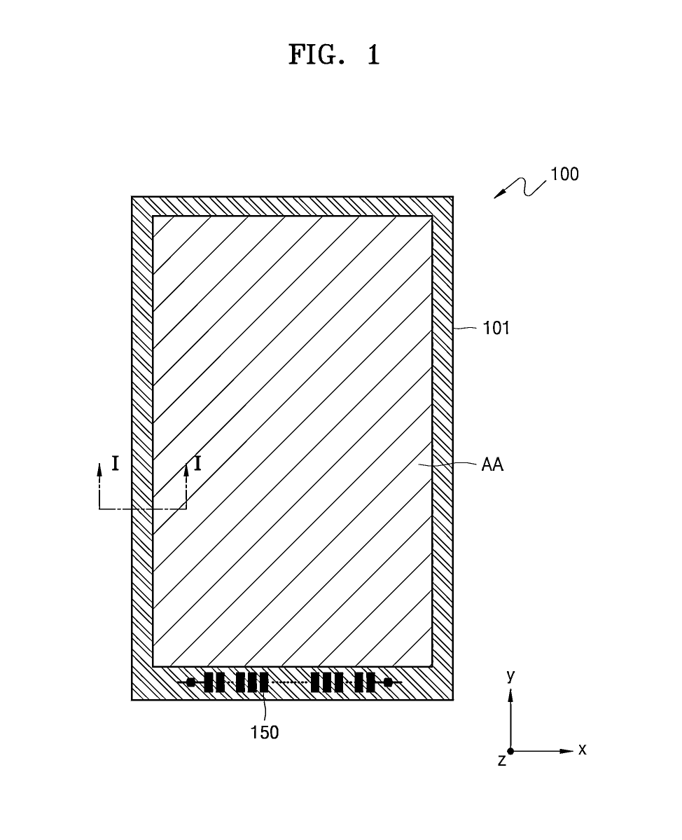

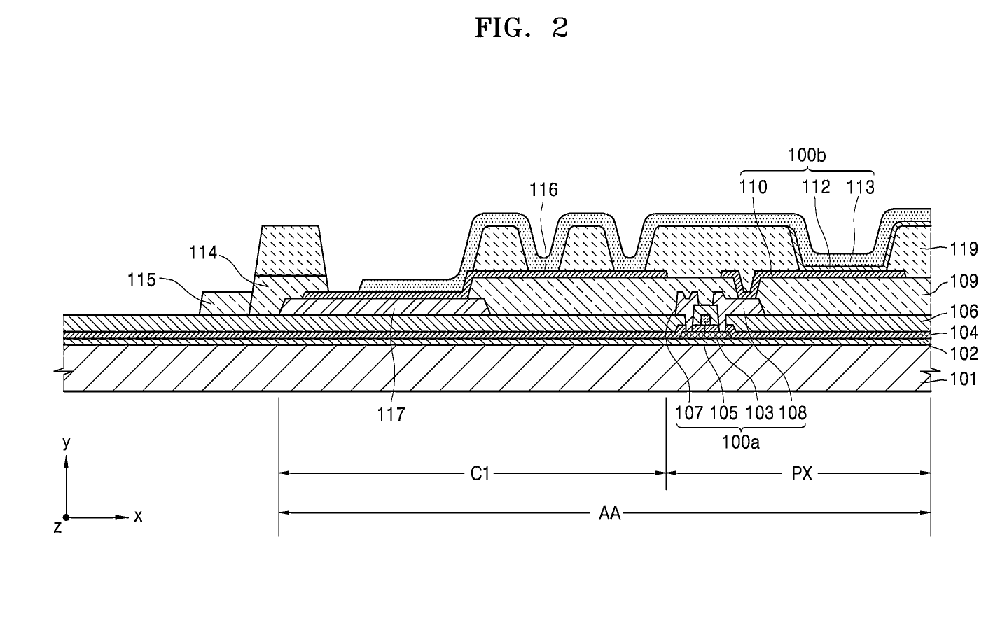

FIG. 1 is a plan view illustrating an organic light-emitting display device 100 according to one embodiment. FIG. 2 is a cross-sectional view of the organic light-emitting display device 100, taken along a line I-I of FIG. 1.

Referring to FIGS. 1 and 2, the organic light-emitting display device 100 may include a substrate 101 that defines a display area AA, and a pixel unit PX and a circuit unit C1 that are formed within the display area AA. A plurality of pad units 150 may be disposed around the display area AA. The pad units 150 may transmit an electric signal from a power supply device (not shown) or a signal generation device (not shown) to the display area AA.

The substrate 101 may be formed of a transparent material. For example, the substrate 101 may be formed of a transparent glass material or a transparent plastic material containing SiO₂.

A buffer layer 102 may be formed on the substrate 101. The buffer layer 102 may be formed on the entire surface of the substrate 101. For example, the buffer layer 102 may be formed on all of the display area AA and an area around the display area AA. The buffer layer 102 may prevent penetration of foreign substances via the substrate 101 and provide a flat surface on the substrate 101. The buffer layer 102 may be formed of various materials capable of performing the functions.

For example, the buffer layer 102 may be a composite layer formed of two or more materials of an inorganic material including silicon oxide, silicon nitride, silicon oxynitride, aluminum oxide, aluminum nitride, titanium oxide, titanium nitride, or the like, and an organic material including polyimide, polyester, acryl, or the like. However, the buffer layer 102 is not an essential element and thus, in some embodiments, the buffer layer 102 may be omitted.

The pixel unit PX and the circuit unit C1 are formed within the display area AA. The pixel unit PX may actually generate a visible ray and may include a thin-film transistor (TFT) 100a and an organic light-emitting diode (OLED) 100b. The circuit unit C1 may have various circuit patterns, e.g., a power supply pattern, a static prevention pattern, and other various circuit patterns.

The TFT 100a includes an active layer 103, a gate electrode 105, a source electrode 107, and a drain electrode 108.

The active layer 103 may be formed of an inorganic semiconductor such as amorphous silicon or polysilicon, an organic semiconductor, or an oxide semiconductor, and may include a source region, a drain region, and a channel region between the source region and the drain region.

A gate insulating layer 104 is formed on the active layer 103. The gate insulating layer 104 may be over the entire surface of the substrate 101. For example, the gate insulating layer 104 may be formed on the display area AA and the area around the display area AA. The gate insulating layer 104 may insulate the active layer 103 from the gate electrode 105 and may be formed of an organic material or an inorganic material including SiNx, SiO₂, or the like.

In the example of FIG. 1, the gate electrode 105 is formed on a predetermined area of the gate insulating layer 104. The gate electrode 105 is connected to a gate line (not shown) that applies on/off signals to the TFT 100a.

The gate electrode 105 may contain Au, Ag, Cu, Ni, Pt, Pd, Al, Mo, or an alloy of Al:Nd or Mo:W. However, one or more embodiments are not limited thereto, and thus, the gate electrode 105 may be formed of various materials, in consideration of a design condition.

An interlayer insulating layer 106 is formed on the gate electrode 105. The interlayer insulating layer 106 is disposed between the gate electrode 105 and the source electrode 107, and between the gate electrode 105 and the drain electrode 108 so as to provide insulation therebetween. The interlayer insulating layer 106 may be formed of an inorganic material including SiNx, SiO₂, or the like.

The source electrode 107 and the drain electrode 108 are formed on the interlayer insulating layer 106. The source electrode 107 and the drain electrode 108 may include one or more metal materials selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The interlayer insulating layer 106 and the gate insulating layer 104 include holes for exposing a source region and a drain region of the active layer 103, and the source electrode 107 and the drain electrode 108 may contact the source region and the drain region of the active layer 103, respectively, via the holes.

While FIG. 1 illustrates the top gate type TFT 100a that sequentially includes the active layer 103, the gate electrode 105, the source electrode 107, and the drain electrode 108, one or more embodiments of the present disclosure are not limited thereto. Thus, the gate electrode 105 may be formed below the active layer 103.

The TFT 100a is electrically connected to the OLED 100b so as to drive the OLED 100b, and is covered by a planarization layer 109. For example, the planarization layer 109 is positioned between the TFT 100a and the OLED 100b.

The planarization layer 109 may be formed of an inorganic insulating layer and/or an organic insulating layer. The inorganic insulating layer may include SiO₂, SiNx, SiON, Al₂O₃, TiO₂, Ta₂O₅, HfO₂, ZrO₂, BST, PZT, or the like, and the organic insulating layer may include polymer derivatives having commercial polymers (PMMA and PS) and a phenol group, an acryl-based polymer, an imide-based polymer, an allyl ether-based polymer, an amide-based polymer, a fluorine-based polymer, a p-xylene-based polymer, a vinylalcohol-based polymer, or a combination thereof. The planarization layer 109 may be formed as a multi-stack including the inorganic insulating layer and the organic insulating layer.

The OLED 100b may be formed on the planarization layer 109, and may include a pixel electrode 110, a common electrode 113, and an intermediate layer 112 interposed between the pixel electrode 110 and the common electrode 113.

The pixel electrode 110 may be formed on the planarization layer 109 and may be electrically connected to the drain electrode 108 through a hole formed in the planarization layer 109.

The pixel electrode 110 may be a reflective electrode, and may include a reflective layer formed of Ag, Mg, Al, Pt, Pd, Au, Ni, Nd, Ir, Cr or a compound including any combination thereof, and a transparent or translucent electrode layer formed on the reflective layer. The transparent or translucent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO).

A pixel defining layer 119 formed of an insulating material is formed on the pixel electrode 110. The pixel defining layer 119 may be formed of an organic insulating material selected from the group consisting of polyimide, polyamide, aryl resin, benzocyclobutane, and phenol resin. The pixel defining layer 119 defines a region of the intermediate layer 112 by exposing a predetermined region of the pixel electrode 110, and the intermediate layer 112 including an organic emission layer (organic EML) (not shown) is disposed in the exposed region.

The organic EML included in the intermediate layer 112 may be a small-molecule organic layer or a polymer organic layer. In addition to the organic EML, the intermediate layer 112 may selectively further include a functional layer such as a hole transport layer (HTL), a hole injection layer (HIL), an electron transport layer (ETL), an electron injection layer (EIL), or the like.

The common electrode 113 may be a transparent or translucent electrode, and may be formed of a metal thin layer having a low work function and including Li, Ca, LiF/Ca, LiF/AI, Al, Ag, Mg or a compound of any of these. Also, an auxiliary electrode layer or a bus electrode, which is formed of a transparent electrode forming material such as ITO, IZO, ZnO or In₂O₃, may be further formed on the metal thin layer.

Thus, the common electrode 113 may transmit light emitted from the organic EML included in the intermediate layer 112. For example, the light emitted from the organic EML may be directly emitted toward the common electrode 113 or may be reflected from the pixel electrode 110 (e.g., formed as the reflective electrode) and then may be transmitted toward the common electrode 113.

However, the organic light-emitting display device 100 according to the present embodiment is not limited to a top-emission type organic light-emitting display device. In another embodiment, the organic light-emitting display device 100 may be a bottom-emission type organic light-emitting display device in which light from the organic EML is emitted toward the substrate 101. In such an embodiment, the pixel electrode 110 may be formed as a transparent or translucent electrode, and the common electrode 113 may be formed as a reflective electrode. In yet another embodiment, the organic light-emitting display device 100 may be a dual-emission type organic light-emitting display device in which light is emitted toward and away from the substrate 101.

The circuit unit C1 may include a circuit line 116, a power line 117, and various circuit patterns such as a static prevention pattern, etc. The circuit line 116 may be formed of the same material as the pixel electrode 110 and may be connected to the common electrode 113. The power line 117 may be formed of the same material as the source electrode 107 or the drain electrode 108.

In the example of FIG. 1, a passivation layer 114 may be formed on a predetermined area on the power line 117. The passivation layer 114 may be formed from substantially the same layer as the planarization layer 109 and may be formed in such a manner that a portion of the planarization layer 109 covers an external portion of the power line 117.

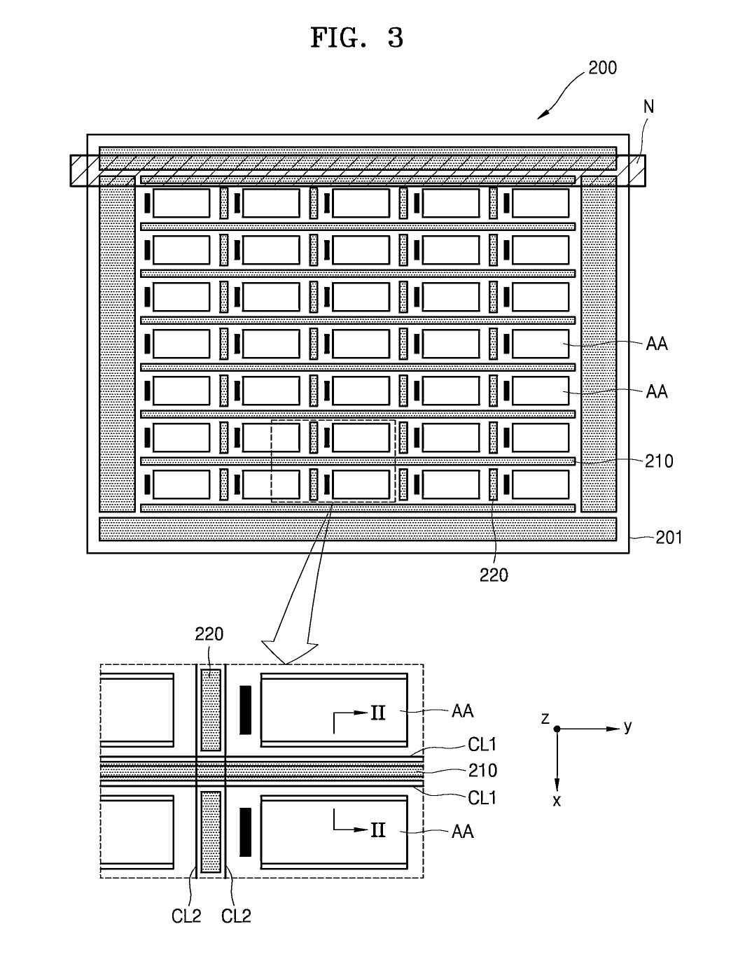

A step compensation layer 115 may be formed at an external side of the passivation layer 114. The step compensation layer 115 may be continuously formed from the passivation layer 114 and may be formed in an outer area of the display area AA. For example, the step compensation layer 115 may be adjacent to the passivation layer 114. The step compensation layer 115 may be formed with a thickness smaller than that of the passivation layer 114, so that a pixel defining layer 119 may be formed with a uniform thickness, as further described in detail with reference to FIGS. 3 through 5.

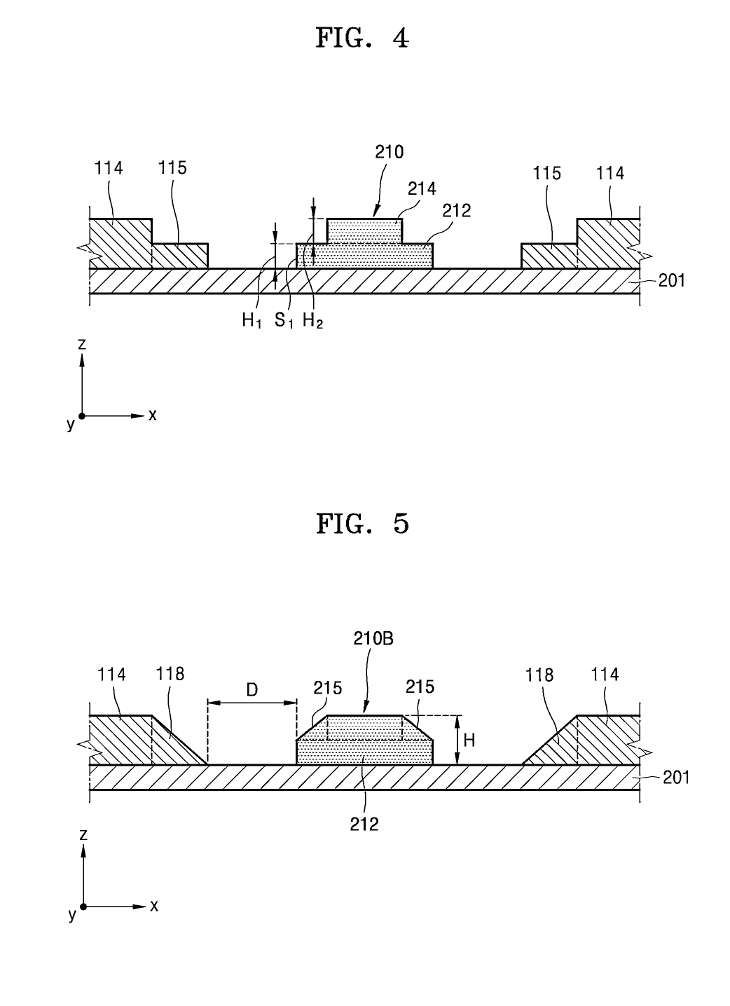

FIG. 3 is a plan view of a mother substrate for organic light-emitting display device 200, according to another embodiment. FIG. 4 is a cross-sectional view of the mother substrate for organic light-emitting display device 200, taken along a line II-II of FIG. 3. FIG. 5 is another cross-sectional view of the mother substrate for organic light-emitting display device 200, taken along the line II-II of FIG. 3.

Referring to FIG. 3, the mother substrate for organic light-emitting display device 200 may include a base substrate 201 having a plurality of display areas AA defined thereon. A plurality of first dummy patterns 210 and a plurality of second dummy patterns 220 which are formed on the base substrate 201.

The base substrate 201 may be the same as or similar to the substrate 101 described with reference to FIG. 2.

The display areas AA may be arranged in an array or matrix, wherein the display areas AA form a plurality of rows and a plurality of columns along a first direction (e.g., an X-axis direction) and a second direction (a Y-axis direction), respectively, where the rows and columns perpendicular to each other. For example, the first direction (e.g., the X-axis direction) may be in parallel with a short side of each of the display areas AA, and the second direction (e.g., the Y-axis direction) may be in parallel with a long side of each of the display areas AA.

FIG. 3 schematically illustrates a process of forming the pixel defining layer 119 (e.g., as shown in FIG. 2) in a procedure of manufacturing the organic light-emitting display device 100 (e.g., using the mother substrate for organic light-emitting display device 200). In the example of FIG. 2, the pixel electrode 110 is formed on the display areas AA. With reference to FIG. 2, processes of forming the pixel electrode 110 will be briefly described.

In one embodiment, the buffer layer 102, the active layer 103, and the gate insulating layer 104 covering the active layer 103 are formed on the substrate 101, and then the gate electrode 105 is formed on the gate insulating layer 104.

The active layer 103 may be formed of amorphous silicon or polysilicon. Here, the polysilicon may be formed by crystallizing the amorphous silicon. The amorphous silicon may be crystallized by using various methods including a rapid thermal annealing (RTA) method, a solid phase crystallization (SPC) method, an excimer laser annealing (ELA) method, a metal-induced crystallization (MIC) method, a metal-induced lateral crystallization (MILC) method, a sequential lateral solidification (SLS) method, and the like.

The gate electrode 105 may be formed above the active layer 103 by having the gate insulating layer 104 interposed therebetween, and the active layer 103 may be doped with impurities by using the gate electrode 105 as a self align mask. For example, the active layer 103 may have a channel region at a position overlapping with the gate electrode 105, and a source region and a drain region that are doped with the impurities at both sides of the channel region.

Afterward, the interlayer insulating layer 106 is formed on the gate electrode 105, the power line 117, the source electrode 107 and the drain electrode 108 are formed on the interlayer insulating layer 106, and then the planarization layer 109 is formed over the source electrode 107 and the drain electrode 108. For example, the planarization layer 109 may cover the source electrode 107 and the drain electrode 108.

The planarization layer 109 may be formed by a photo-resist procedure in which an insulating layer to be formed as the planarization layer 109 is coated on the source electrode 107 and the drain electrode 108, and partially exposed using a mask. An exposed region or a non-exposed region of the insulating layer may be patterned by etching. Here, the mask may be a halftone mask. Thus, the process used for forming the planarization layer 109 may also form the passivation layer 114 covering the external portion of the power line 117 and the step compensation layer 115 that is adjacent to the passivation layer 114 and has a height lower than that of the passivation layer 114.

In one embodiment, the first dummy patterns 210 and the second dummy patterns 220 may be formed of the same material as the planarization layer 109. The first dummy patterns 210 may be formed in the second direction between the rows formed by the display areas AA. The first dummy patterns 210 may extend beyond the edges of the array of the display areas AA. The second dummy patterns 220 may be formed between the adjacent columns of display areas AA in the first direction.

Afterward, the circuit line 116 that contacts the power line 117, and the pixel electrode 110 are formed on the planarization layer 109. The pixel defining layer 119 is formed on the pixel electrode 110.

The pixel defining layer 119 may be formed by a photo-resist procedure (e.g., as illustrated in FIG. 3), in which a nozzle unit N may spray an insulating solution to form the pixel defining layer 119 on an entire surface of the base substrate 201 as the nozzle unit N moves along the first direction (e.g., the X-axis direction) above the base substrate 201 where the display areas AA are arranged in the array. The insulating solution may be partially exposed using a mask and then patterned by etching.

Here, the first dummy patterns 210 and the second dummy patterns 220 which are formed in empty spaces between the rows and columns of display areas AA may reduce the loading effect when exposing and etching processes are performed to form the pixel defining layer 119, so that the pixel defining layer 119 may be formed with a uniform pattern and/or uniform thickness.

In some cases, the first dummy patterns 210 or the second dummy patterns 220 may function as a dam when the insulating solution is sprayed, such that the first dummy patterns 210 or the second dummy patterns 220 may prevent the insulating solution from being formed with a uniform thickness. For example, when the insulating solution is sprayed on the base substrate 201 along the movement direction of the nozzle unit N, the insulating solution may be pushed in a direction opposite to the movement direction of the nozzle unit N by the side of the first dummy patterns 210 that faces the direction opposite to the movement direction of the nozzle unit N. Also, the aforementioned dam effect may be further increased as a gap between the display areas AA becomes narrow due to more display areas AA being disposed on the mother substrate for organic light-emitting display device 200 to improve efficiency in manufacturing the organic light-emitting display device 100.

In some embodiments, in order to prevent the above-described problem, the first dummy pattern 210 or the second dummy pattern 220 may have a step. Here, the first dummy pattern 210 or the second dummy pattern 220 that has the step may be formed in a direction perpendicular to the movement direction of the nozzle unit N. For example, as illustrated in FIG. 3, when the nozzle unit N moves along the first direction (e.g., the X-axis direction), the first dummy patterns 210 that are formed in the second direction (e.g., the Y-axis direction) may have a step.

FIG. 4 is a cross-sectional view of the mother substrate for organic light-emitting display device 200, taken along a line II-II of FIG. 3, and referring to FIG. 4, the first dummy pattern 210 that is formed in a direction perpendicular to the movement direction of the nozzle unit N may include a first layer 212 and a second layer 214 on the first layer 212, and here, a width of the second layer 214 (e.g., in a column direction parallel to the plurality of columns of display areas) is smaller than a width of the first layer 212. Similar to the step compensation layer 115, the first dummy patterns 210 having a step may be formed simultaneously or in the same processing step as when the planarization layer 109 is formed by using the halftone mask.

For example, if the first layer 212 is formed with a height H₁ and the second layer 214 is formed with a height H₂, when an insulating solution is sprayed on the base substrate 201 as the nozzle unit N moves along the first direction (e.g., the X-axis direction), the area that the insulating solution initially contacts (e.g., a side surface S1 of the first dummy pattern 210) is reduced, and the height to be overcome by the insulating solution is decreased. Thus, uniformity in spraying the insulating solution may be improved.

On the other hand, when the first dummy pattern 210 is not formed with the step, a height of the first dummy pattern 210 corresponds to a sum of H₁+H₂, such that, when the insulating solution contacts the side surface S1 of the first dummy pattern 210, the insulating solution is met with a greater resistance, and thus the insulating solution may be pushed in an opposite direction of a spray direction of the insulating solution after contacting the side surface S1 of the first dummy pattern 210. As a result, the insulating solution may further coat the region on the display area AA that has already been coated with the insulating layer (e.g., the region over which the nozzle unit N has already passed), such that a spot may occur on the organic light-emitting display device 100.

Similarly, the step compensation layer 115 having a height lower than that of the passivation layer 114 may improve uniformity in spraying the insulating solution. For example, when the nozzle unit N passes the first dummy pattern 210 and moves above another display area AA, if the step compensation layer 115 is not formed in the other display area AA, the aforementioned dam effect may occur due to the passivation layer 114, so that the insulating solution may be thinly sprayed on the other display area AA.

Thus, according to the one or more embodiments of the present disclosure, the first dummy patterns 210 formed in a direction perpendicular to the movement direction of the nozzle unit N have a step, and the step compensation layer 115 is formed in the external side of the passivation layer 114 (e.g., away from the center of the display area), so that, even if a greater number of display areas AA are disposed on the mother substrate for organic light-emitting display device 200 (e.g., thereby causing the areas between the columns and rows of display areas to be smaller), the pixel defining layer 119 may be formed with a uniform thickness. Thus, efficiency in manufacturing the organic light-emitting display device 100, and an image quality of the organic light-emitting display device 100 may be improved.

In the embodiment of FIG. 4, each of the first dummy patterns 210 includes the first layer 212 and the second layer 214, but one or more embodiments of the present disclosure are not limited thereto. For example, each of the first dummy patterns 210 may be formed with three or more layers. In one embodiment, each of the first dummy patterns 210 may have a stair-shape in which an upper width is smaller than a lower width. Also, as illustrated in FIG. 5, each of the first dummy patterns 210 may have a slope 215.

FIG. 5 is another cross-sectional view of the mother substrate for organic light-emitting display device, taken along the line II-II of FIG. 3. Referring to FIG. 5, a first dummy pattern 2108 may have a side surface that is slanted with respect to the surface of the base substrate 201 (e.g., the slope 215 shown in FIG. 5). Here, the slope 215 may be formed in such a manner that a plurality of layers are stacked on a first layer 212 (e.g., a plurality of smaller steps) while upper widths of the plurality of layers are smaller than lower widths of the plurality of layers. Thus, the first dummy pattern 2108 of FIG. 5 is formed with a step.

Also, referring to FIG. 5, although the slope 215 starts from a predetermined height in the example of FIG. 5, in another embodiment, the slope 215 may start from a top surface of a base substrate 201. For example, the slope 215 may be formed on the entire side surface of the first dummy pattern 2108. When the side surface of the first dummy pattern 2108 is formed as the slope 215, uniformity in spraying an insulating solution for forming the pixel defining layer 119 may be improved.

A degree of the slope 215 may be set to an arbitrary angle, in consideration of a difference D between a step compensation layer 118 and the first dummy pattern 210B a height H of the first dummy pattern 210B viscosity and a surface tension of the sprayed insulating solution, or the like.

In order to improve the uniformity in spraying the insulating solution, the step compensation layer 118 may also have a slope. Here, the height of the slope may decrease as the slope slants toward an outside of the display area AA, as illustrated in FIG. 5.

Referring back to FIGS. 2 and 4, after the pixel defining layer 119 is formed, the intermediate layer 112 and the common electrode 113 may be formed, an encapsulation member (not shown) may be formed on the common electrode 113 in a subsequent process. Subsequently, first cutting lines CL1 between the first dummy patterns 210 and the display areas AA, and second cutting lines CL2 between the second dummy patterns 220 and the display areas AA may be cut, so that the organic light-emitting display device 100 may be formed.

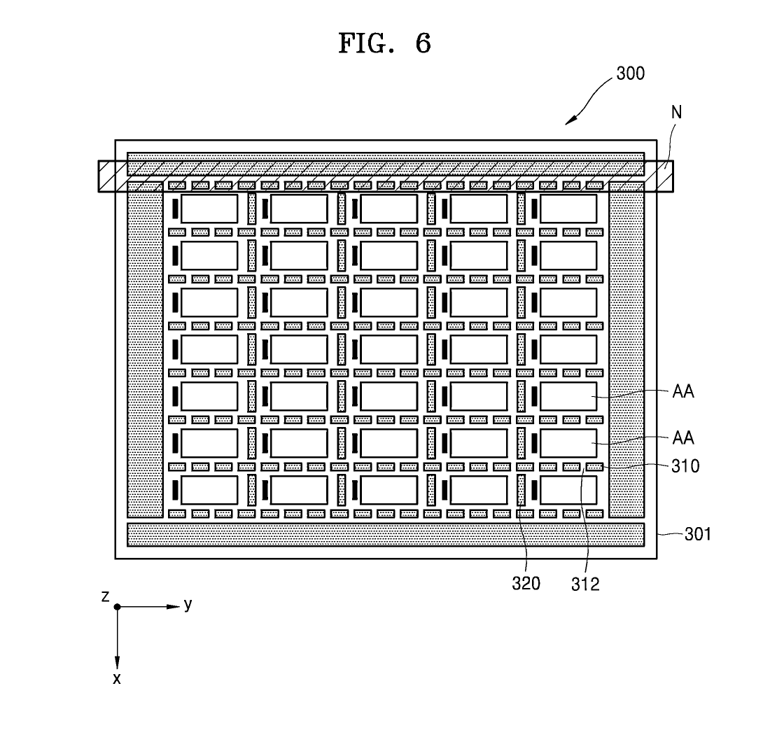

FIG. 6 is a plan view illustrating a modified example of the mother substrate for organic light-emitting display device 200 of FIG. 3.

Referring to FIG. 6, a mother substrate for organic light-emitting display device 300 may include a base substrate 301 having a plurality of display areas AA defined thereon. Additionally, the base substrate 301 may include a plurality of first dummy patterns 310 and a plurality of second dummy patterns 320 formed thereon.

Similar to the embodiment of FIG. 3, FIG. 6 schematically illustrates how the pixel defining layer 119 (e.g., as shown in FIG. 2) is formed in a process of manufacturing the organic light-emitting display device 100 (e.g., by using the mother substrate for organic light-emitting display device 300). Thus, hereinafter, only the differences from the embodiment of FIG. 3 will be described with reference to FIG. 6.

The pixel defining layer 119 may be formed by a photoresist procedure in which a nozzle unit N sprays an insulating solution on the base substrate 301 as the nozzle unit N moves along a first direction (e.g., an X-axis direction). The insulating solution may be partially exposed by using a mask and the exposed region or the non-exposed region of the insulating layer may be patterned by etching.

Here, each of the first dummy patterns 310 formed along a direction perpendicular to the movement direction of the nozzle unit N may include a plurality of cut portions 312. The cut portions 312 are areas where the first dummy patterns 310 are partially removed or are not formed, and because the insulating solution, which is sprayed by the nozzle unit N as the nozzle unit N moves along the first direction (e.g., the X-axis direction), may easily move in the first direction (e.g., the X-axis direction) through the cut portions 312, uniformity in spraying the insulating solution may be improved. The cut portions 312 may be separated from each other by a regular (e.g., fixed, uniform, or predetermined) distance.

Although not illustrated, each of the first dummy patterns 310 may have a step. In more detail, as illustrated in FIG. 4, each of the first dummy patterns 310 may have a stair-shape in which an upper width is smaller than a lower width, or as illustrated in FIG. 5, each of the first dummy patterns 310 may have a side surface that is slanted with respect to the surface of the base substrate on which the first dummy patterns 310 are formed.

According to the one or more of the above embodiments of the present invention, efficiency in manufacturing the organic light-emitting display device, and an image quality of the organic light-emitting display device may be improved.

It should be understood that the exemplary embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and detail may be made therein without departing from the spirit and scope of the present disclosure as defined by the following claims.

What is claimed is:

1. A mother substrate for an organic light-emitting display device, the mother substrate comprising:
a base substrate;
a plurality of display areas arranged in an array on the base substrate, the array having a plurality of rows and a plurality of columns that are perpendicular to the plurality of rows; and
a plurality of first dummy patterns formed between the plurality of rows of display areas;
a plurality of second dummy patterns formed between the plurality of columns of display areas,
wherein each of the plurality of first dummy patterns comprises a top portion and a bottom portion, the bottom portion being closer to the base substrate than the top portion and having a width, in a column direction parallel to the plurality of columns, that is greater than a width of the top portion in the column direction.

2. The mother substrate of claim 1, wherein each of the plurality of first dummy patterns comprises a first layer and a second layer on the first layer, the first layer forming the bottom portion and the second layer forming the top portion.

3. The mother substrate of claim 1, wherein each of the plurality of first dummy patterns has a stair-shape in which an upper width is smaller than a lower width.

4. The mother substrate of claim 1, wherein each of the plurality of first dummy patterns comprises a side surface that is slanted with respect to a major surface of the base substrate over which the plurality of first dummy patterns are formed.

5. The mother substrate of claim 1, wherein each of the plurality of first dummy patterns comprises a plurality of cut portions.

6. The mother substrate of claim 5, wherein the plurality of cut portions are separated from each other by a uniform distance.

7. The mother substrate of claim 1, wherein each of the plurality of display areas comprises a pixel comprising a thin-film transistor (TFT) and an organic light-emitting diode (OLED), and a circuit comprising a power line,
wherein a planarization layer is disposed between the TFT and the OLED, and
wherein a portion of the planarization layer forms a passivation layer that covers an external portion of the power line.

8. The mother substrate of claim 7, further comprising a step compensation layer formed at an external side of the passivation layer that is farther away from the center of the display area, and
wherein the step compensation layer has a height that is smaller than a height of the passivation layer.

9. The mother substrate of claim 8, wherein the step compensation layer is adjacent to the passivation layer.

10. The mother substrate of claim 8, wherein the step compensation layer is formed of the same material as the planarization layer.

11. The mother substrate of claim 8, wherein the step compensation layer has a slope whose height decreases as the slope slants away from the plurality of display areas.

12. The mother substrate of claim 8, wherein the step compensation layer is positioned outside the plurality of display areas.

13. The mother substrate of claim 7, wherein the plurality of first dummy patterns and the plurality of second dummy patterns are formed of the same material as the planarization layer.

14. The mother substrate of claim 1, further comprising first cutting lines between the plurality of first dummy patterns and the rows of display areas, and second cutting lines between the plurality of second dummy patterns and the columns of display areas.

15. An organic light-emitting display device comprising:
a substrate for defining a display area;
a pixel formed within the display area;
a circuit formed within the display area and comprising a power line; and
a step compensation layer formed outside the display area,
wherein the pixel comprises a thin-film transistor (TFT), an organic light-emitting diode (OLED), and a planarization layer between the TFT and the OLED,
wherein the planarization layer forms a passivation layer that covers an external portion of the power line, and
wherein the step compensation layer is formed at an external side of the passivation layer that is farther away from the center of the display area, and has a height that is smaller than a height of the passivation layer.

16. The organic light-emitting display device of claim 15, wherein the step compensation layer is formed of the same material as the planarization layer.

17. The organic light-emitting display device of claim 15, wherein the step compensation layer is the passivation layer.

18. The organic light-emitting display device of claim 15, wherein the step compensation layer comprises a side surface that is slanted with respect to a major surface of the substrate over which the step compensation layer is formed.

19. The organic light-emitting display device of claim 18, wherein a height of the slope decreases as the slope slants away from the display area.

20. The mother substrate of claim 1, wherein each of the plurality of first dummy patterns comprises a side surface that is slanted with respect to a major surface of the base substrate over which the plurality of first dummy patterns are formed, the side surface disposed at a predetermined height from the major surface.
